(19) United States
(12) Patent Application Publication
(10) Pub. No.: US 2024/0125821 A1
(43) Pub. Date: Apr. 18, 2024

(54) WIDEBAND MEASUREMENT SYSTEM FOR MIXED-CONNECTED CAPACITIVE VOLTAGE TRANSFORMER BASED ON OPTICAL VOLTAGE SENSOR

(71) Applicant: HARBIN INSTITUTE OF TECHNOLOGY, Harbin (CN)

(72) Inventors: Guoqing ZHANG, Harbin (CN); Wenbin YU, Harbin (CN); Caiyun MO, Harbin (CN); Yuxin ZHANG, Harbin (CN); Jie ZUO, Harbin (CN)

(73) Assignee: HARBIN INSTITUTE OF TECHNOLOGY, Harbin (CN)

(21) Appl. No.: 18/544,543

(22) Filed: Dec. 19, 2023

Related U.S. Application Data
(63) Continuation of application No. PCT/CN2023/116305, filed on Aug. 31, 2023.

(30) Foreign Application Priority Data
Sep. 2, 2022 (CN) 202211072845.2

(51) Int. Cl. G01R 15/22; G01R 19/10

(52) U.S. Cl. CPC G01R 15/22; G01R 19/10

(57) ABSTRACT

A schematic diagram of a wideband measurement system for mixed-connected CVT based on an optical voltage sensor is provided. The wideband measurement system comprises a CVT power frequency measurement section and an optical wideband measurement section. In the optical wideband measurement section, a low-voltage capacitor is connected in series between the low-voltage terminal and the ground terminal of the medium-voltage capacitor in the capacitor voltage divider. An optical voltage sensor is connected in parallel across the terminals of the low-voltage capacitor to measure the wideband voltage signal under test. The wideband measurement system for mixed-connected CVT described in the invention enables the CVT to have wideband measurement capabilities while ensuring the accuracy of conventional CVT power frequency measurements.

### CROSS REFERENCE TO THE RELATED APPLICATIONS

This application is a continuation application of International Application No. PCT/CN2023/116305, filed on Aug. 31, 2023, which is based upon and claims priority to Chinese Patent Application No. 202211072845.2, filed on Sep. 2, 2022, the entire contents of which are incorporated herein by reference.

### TECHNICAL FIELD

The present invention belongs to the technical field of voltage measurement in power systems.

### BACKGROUND

Currently, the Capacitor Voltage Transformers (CVT) is widely used in power grids with voltage levels of 220 kV and above in domestic. The structure and parameters of conventional CVT is designed based on the resonance condition at the power frequency. The inductive reactance of compensation reactor in the CVT is matched with the capacitive reactance of the voltage divider at the power frequency, ensuring accurate measurement. However, when the CVT is used to measure non-power frequency signals such as harmonics and transient signals in the power grid, the impedance matching inside the CVT is disrupted, resulting in severe nonlinearity in the frequency response characteristics at different ratios. This leads to significant output errors that cannot meet the accuracy requirements of the power quality monitoring system for data sources. The Chinese standard GB/T 14549-1993 states that “capacitive voltage transformers cannot be used for harmonic measurement,” and similar restrictions are mentioned in IEC standards and relevant technical reports, stating that CVT is not suitable for measuring non-power frequency voltage signals such as harmonics and transient signals.

The transient overvoltage in power grids poses a threat to the safe operation of power equipment, and monitoring the transient over-voltage is crucial for ensuring the safe and reliable operation of the grid. However, there is currently no effective means of monitoring the transient overvoltage, and there is a lack of recorded data on it during accidents. Analysis of accidents caused by transient overvoltage mainly relies on experience, resulting in unclear identification of the accident causes. Utilizing a real-time transient overvoltage monitoring system to record the entire process of fault occurrence allows for accurate determination of the accident causes through analysis of recorded voltage data. This is of significant importance for improving equipment insulation levels and implementing necessary preventive measures. However, in current engineering implementations, due to the absence of well-established practical online monitoring methods for overvoltage and the lack of mandatory requirements for installing transient overvoltage monitoring systems, the availability of field-measured data on the transient overvoltage is extremely limited.

The frequency characteristics of new power systems with renewable energy as their main source pose significant challenges. Firstly, in high-penetration renewable energy grids, such as those with large-scale wind and solar power capacities, the uncertain power generation from these sources can disrupt power balance in the grid, placing higher demands on grid frequency control techniques. Secondly, the widespread use of power electronic devices has introduced a greater variety of frequency components into the grid. The frequency characteristics of high-penetration renewable energy grids encompass not only low-frequency characteristics and high-frequency characteristics but also fundamental frequency fluctuations caused by uncertain power generation. The wideband characteristics of the new power system necessitate wideband measurement requirements for voltage transformers.

### SUMMARY

Due to the high requirements for grid frequency control technology and the presence of fundamental frequency fluctuations caused by uncertain power generation in the frequency characteristics of renewable energy grids, as well as the monitoring requirements for transient overvoltage in the grid, wideband measurements are needed. In light of this, the present invention proposes a wideband measurement system for mixed-connected CVT based on an optical voltage sensor.

A wideband measurement system for mixed-connected CVT based on an optical voltage sensor is proposed in this paper, including a CVT power frequency measurement part and an optical wideband measurement part. The optical wideband measurement part comprises a low-voltage capacitor, an optical voltage sensor, a signal processing unit, and a monitoring and analysis host.

In the CVT power frequency measurement part, a low-voltage capacitor is connected in series between the low-voltage terminal and the ground terminal of the capacitor voltage divider. The electrodes of the optical voltage sensor are connected in parallel across the two terminals of the low-voltage capacitor. Under the triggering of the superluminescent diode (SLD) light source in the signal processing unit, the optical voltage sensor divides the light signal modulated by the low-voltage capacitor into two beams and directs them to the signal processing unit. The signal processing unit converts the two incident light signals into two voltage signals uₒ₁ and uₒ₂, obtaining the mid-to-low voltage signal u_{oL}(f₁) and the high-frequency voltage signal u_{oH}(f₂), respectively. The monitoring and analysis host collects the mid-to-low voltage signal u_{oL}(f₁) and the high-frequency voltage signal u_{oH}(f₂), and calculates to obtain the wideband voltage signal on the primary side.

Furthermore, the aforementioned signal processing unit consists of a low-pass filtering circuit, a 1# bandpass filter amplifier circuit, a 2# bandpass filter amplifier circuit, a 1# divider, a 2# divider, a 3# divider, a 4# divider, a 1# subtractor, a 2# subtractor, an SLD light source, a 1# photodetector, and a 2# photodetector.

The SLD light source serves as the triggering light source for the optical voltage sensor.

The two beams of light emitted by the optical voltage sensor are respectively converted into voltage signals uₒ₁ and uₒ₂ through the 1# photodetector and the 2# photodetector.

The low-pass filtering circuit extracts the direct-current (DC) bias voltages Uₛ₁ and Uₛ₂ from the two voltage signals uₒ₁ and uₒ₂, respectively.

The 1# bandpass filter amplifier circuit applies bandpass filtering and amplification processes to the voltage signals uₒ₁ and uₒ₂, respectively, resulting in the extraction of the mid-to-low frequency voltage signals u_{1L}(f₁) and u_{2L}(f₁). Similarly, the 2# bandpass filter amplifier circuit performs bandpass filtering and amplification on the voltage signals uₒ₁ and uₒ₂, obtaining high-frequency voltage signals u_{1H}(f₂) and u_{2H}(f₂).

The 1# divider calculates the quotient A between the mid-to-low frequency voltage signal u_{1L}(f₁) and the DC bias voltage Uₛ₁. The 2# divider calculates the quotient B between the mid-to-low frequency voltage signal u_{2L}(f₁) and the DC bias voltage Uₛ₂. The 3# divider calculates the quotient C between the high-frequency voltage signal u_{1H}(f₂) and the DC bias voltage Uₛ₁. The 4# divider calculates the quotient D between the high-frequency voltage signal u_{2H}(f₂) and the DC bias voltage Uₛ₂.

The 1# subtractor computes the difference between the quotient A and the quotient B to obtain the mid-to-low frequency voltage signal u_{oL}(f₁). Similarly, the 2# subtractor computes the difference between the quotient C and the quotient D to obtain the high-frequency voltage signal u_{oH}(f₂).

Furthermore, the aforementioned monitoring and analysis host calculates the wideband voltage signal on the primary side based on the following equation.

u_{oL}(f₁)=G₁kK_{C}u₁(f₁),

u_{oH}(f₂)=G₂kK_{C}u₁(f₂),

Where G₁ and G₂ represent the amplification factors of the 1# and 2# bandpass filter amplifier circuits, respectively. u₁(f₁) and u₂(f₂) denote the mid-to-low frequency voltage component and the high-frequency voltage component, respectively. u₁ represents the wideband voltage signal on the primary side loaded at the voltage monitoring terminal, which is the high-voltage end of the voltage divider. k is the electro-optic constant, and K_{C} is the voltage division ratio of the low-voltage capacitor.

Furthermore, the aforementioned 1# photodetector converts the received optical signal into a voltage signal uₒ₁. Similarly, the 2# photodetector converts the received optical signal into a voltage signal uₒ₂. The expressions for the voltage signals uₒ₁ and uₒ₂ are as follows:

uₒ₁=Uₛ₁(1+kK_{C}u₁),

uₒ₂=Uₛ₂(1−kK_{C}u₁),

Where Uₛ₁ and Uₛ₂ are the DC bias voltages for uₒ₁ and uₒ₂, respectively.

Furthermore, the expressions for the mid-to-low frequency voltage signals u_{1L}(f₁) and u_{2L}(f₁) are as follows:

u_{1L}(f₁)=G₁Uₛ₁kK_{C}u₁(f₁),

u_{2L}(f₁)=−G₁Uₛ₂kK_{C}u₁(f₁),

The expressions for the high-frequency voltage signals u_{1H}(f₂) and u_{2H}(f₂) are as follows:

u_{1H}(f₂)=G₂Uₛ₁kK_{C}u₁(f₂),

u_{2H}(f₂)=−G₂Uₛ₂kK_{C}u₁(f₂),

Where Uₛ₁ and Uₛ₂ are the DC bias voltages for uₒ₁ and uₒ₂, respectively.

Furthermore, the cutoff frequency of the above low-pass filter circuit is 0.1 Hz.

The lower limit cutoff frequency of the 1# bandpass filter amplifier circuit is 1 Hz, and the upper limit cutoff frequency is set to 10 kHz.

The lower limit cutoff frequency of the 2# bandpass filter amplifier circuit is 10 kHz, and the upper limit cutoff frequency is set to 50 MHz.

Furthermore, the above-mentioned voltage signals in the medium-low frequency range u_{oL}(f₁), and the voltage signals in the high frequency range u_{oH}(f₂) are respectively sent to the monitoring and analysis host through the data acquisition card.

Furthermore, the aforementioned optical wideband measurement section also includes a voltage limiting device, which is connected in parallel across the terminals of the low-voltage capacitor.

Furthermore, the aforementioned capacitor voltage divider includes series-connected high-voltage and medium-voltage capacitors, with the low-voltage capacitor connected in series between the low-voltage terminal and the ground terminal of the medium-voltage capacitor.

The expression for the terminal voltage of the low-voltage capacitor u_{C3} is as follows:

$${u}_{C 3} = \frac{{C}_{1} {C}_{2}}{{C}_{1} {C}_{2} + {C}_{1} {C}_{3} + {C}_{2} {C}_{3}} {u}_{1} = {K}_{C} {u}_{1} ,$$

Where C₁, C₂, and C₃ represent the capacitance values of the high-voltage capacitor, medium-voltage capacitor, and low-voltage capacitor respectively. K_{C} is the voltage divider ratio of the low-voltage capacitor, and u₁ is the wideband voltage signal from the primary side connected to the voltage monitoring terminal.

Furthermore, the material of the low-voltage capacitor mentioned above is the same as that of the high-voltage and medium-voltage capacitors.

The beneficial effects of the present invention are as follows:
(1) The proposed wideband measurement system for mixed-connected CVT based on an optical voltage sensor is an extended modification of the conventional CVT. It involves connecting a low-voltage capacitor in series between the low-voltage terminal and the ground terminal of the conventional CVT. This forms a voltage divider circuit with the high-voltage capacitor and the medium-voltage capacitor of the original CVT's capacitor voltage divider. Consequently, it achieves wideband measurement functionality encompassing measurements of power-frequency voltage, harmonic voltage, and transient high-frequency voltage.
(2) The low-voltage capacitor used in this invention is implemented in parallel using capacitor components with the same material, structure, and process as the high-voltage and medium-voltage capacitors of the original capacitor voltage divider of the conventional CVT. This not only ensures that the addition of the low-voltage capacitor does not affect the lifespan of the original CVT product, but also guarantees that the voltage divider ratio of the low-voltage capacitor remains unaffected by temperature variations.
(3) The optical voltage sensor used in this invention is a passive sensor, composed entirely of optical insulation materials. It does not require a power supply in the field and is connected to the signal processing module located in the control room via optical cables. It has strong immunity to electromagnetic interference and is not easily affected by harsh electromagnetic environments in the field. The sensor exhibits excellent stability, high reliability, good safety, and strong resistance to electromagnetic interference.
(4) The signal processing solution of the signal processing unit in this invention employs different bandpass filters to separate and process the mid-to-low frequency voltage signals and high-frequency voltage signals. This approach effectively enhances the signal-to-noise ratio and reduces the impact of noise on measurement accuracy.

### BRIEF DESCRIPTION OF THE DRAWINGS

FIG. 1 illustrates the schematic diagram of a wideband measurement system for mixed-connected CVT based on an optical voltage sensor, as described in this invention.

FIG. 2 depicts the schematic diagram of the signal processing principle within the signal processing unit.

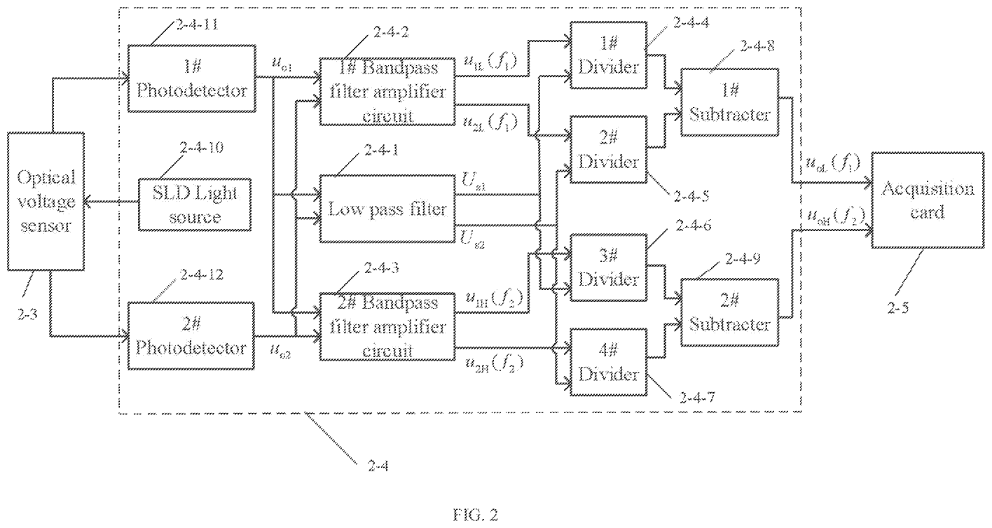

FIG. 3 shows the schematic diagram of the structure of the optical voltage sensor.

### DETAILED DESCRIPTION OF THE EMBODIMENTS

In the following sections, the technical solutions in the exemplary embodiments of the present invention will be described in a clear and comprehensive manner, in conjunction with the accompanying drawings. It is evident that the described embodiments are only a part of the implementation of the present invention, and not the entirety of the embodiments. Based on the embodiments disclosed herein, all other embodiments obtained by those skilled in the art without inventive efforts are also within the scope of protection of the present invention. It should be noted that, unless conflicting, the embodiments and the features in the embodiments of the present invention can be combined with each other.

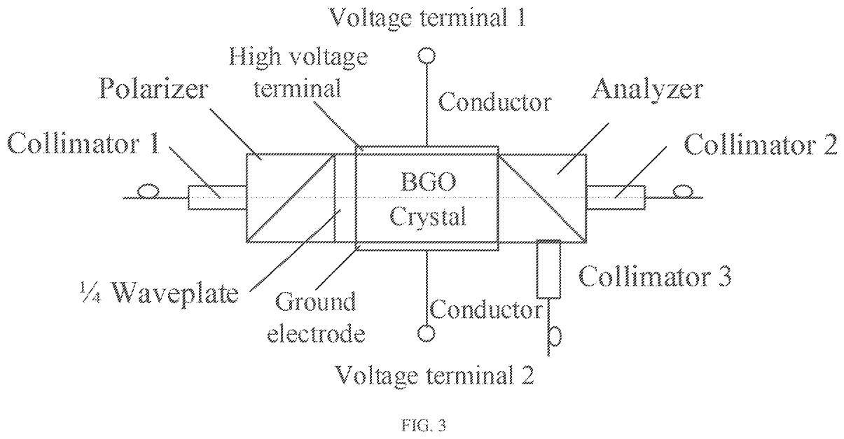

As shown in FIG. 3, the LED light source emits a carrier light signal of a certain wavelength, which is transmitted along the optical fiber to the collimator 1. The light then passes through a polarizer, and converts into linearly polarized light. Subsequently, the linearly polarized light passes through a λ/4 waveplate, and transforms into circularly polarized light. When the circularly polarized light passes through the BOO electro-optic crystal, it undergoes birefringence under the influence of voltage, resulting in elliptically polarized light. After passing through an analyzer, the elliptically polarized light is converted into linearly polarized light with intensity proportional to the measured voltage. The analyzer splits the output light into two beams in a 1:1 ratio, which are aggregated by collimator 2 and collimator 3, respectively, and then transmitted through optical fibers to the photodetector for photoelectric conversion. The measured voltage is obtained by demodulation using a signal processing circuit.

The optical voltage sensor is based on the Pockels electro-optic effect to sense voltage. Light passing through the polarizer of the optical voltage sensor generates linearly polarized light. Under the influence of the measured voltage u, the linearly polarized light passes through the BOO crystal. The two beams of light emitted exhibit a phase difference δ, represented as follow.

δ=ku,

In the equation, k represents the electro-optic coefficient.

In principle, the optical voltage sensor does not have bandwidth and response time issues. It can accurately convert voltage signals and is considered a passive sensor. The processing circuit and the sensor are connected via an optical cable, enabling complete electrical isolation between the primary and secondary of the monitoring system. The optical voltage sensor is an ideal wideband voltage sensing device for power systems.

Based on the above principles, to realize the wideband modification of conventional CVTs with widespread application in power systems, this implementation proposes a wideband monitoring system for mixed-connected CVT based on an optical voltage sensor. In this system, a low-voltage capacitor is connected in series between the low-voltage terminal and the ground terminal of the conventional CVT. This forms a voltage divider circuit with the high-voltage and medium-voltage capacitors of the original CVT's capacitor voltage divider, enabling simultaneous measurement of power frequency voltage, harmonic voltage, and transient high-frequency voltage.

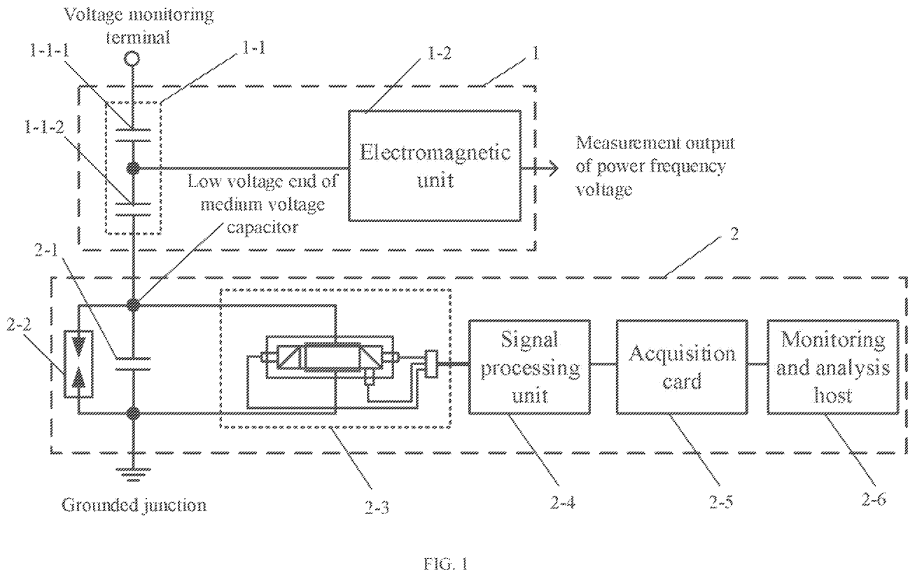

Referring to FIG. 1, this embodiment specifically describes a optical voltage sensor-based wideband measurement system for the mixed-connected CVT. The system includes a power frequency measurement part 1 and an optical wideband measurement part 2. The power frequency measurement part 1 is used to measure the tested power frequency voltage signal. It consists of a capacitor voltage divider 1-1 and an electromagnetic unit 1-2. The capacitor voltage divider 1-1 consists of series-connected high voltage capacitor 1-1-1 and medium voltage capacitor 1-1-2. The optical wideband measurement part 2 includes: a low-voltage capacitor 2-1, a voltage limiting device 2-2, an optical voltage sensor 2-3, a signal processing unit 2-4, an acquisition card 2-5, and a monitoring and analysis host 2-6.

The signal processing unit 2-4 includes: a low-pass filtering circuit 2-4-1, a 1# bandpass filter amplifier circuit 2-4-2, a 2# bandpass filter amplifier circuit 2-4-3, a 1# divider 2-4-4, a 2# divider 2-4-5, a 3# divider 2-4-6, a 4# divider 2-4-7, a 1# subtractor 2-4-8, a 2# subtractor 2-4-9, an SLD light source 2-4-10, a 1# photodetector 2-4-11, and a 2# photodetector 2-4-12.

The low-voltage capacitor 2-1 is connected in series between the low-voltage terminal and the ground terminal of the capacitor voltage divider 1-1 in the power frequency measurement part 1 of the CVT. It forms a voltage divider circuit with the high-voltage capacitor 1-1-1 and the medium voltage capacitor 1-1-2 of the original CVT's capacitor voltage divider. The material of the low-voltage capacitor 2-1 is the same as that of the high-voltage capacitor 1-1-1 and the medium voltage capacitor 1-1-2. This ensures that adding the low-voltage capacitor 2-1 does not affect the lifespan of the original CVT product and also guarantees that the voltage division ratio of the low-voltage capacitor 2-1 is not influenced by temperature changes. The voltage limiting device 2-2 is connected in parallel between the two terminals of the low-voltage capacitor 2-1, serving the purpose of limiting overvoltage.

The optical voltage sensor 2-3 is installed locally in the equipment base enclosure and is connected to the signal processing unit 2-4 located in the control room through an optical cable. The electrodes of the optical voltage sensor 2-3 are connected in parallel to the terminals of the low-voltage capacitor 2-1. The SLD light source 2-4-10 serves as the triggering light source for the optical voltage sensor 2-3. When triggered by the SLD light source 2-4-10, the optical voltage sensor 2-3 splits the light signal modulated by the low-voltage capacitor 2-1 and into two beams. These two beams are then incident on the 1# photodetector 2-4-11 and the 2# photodetector 2-4-12, respectively, and are converted into voltage signals uₒ₁ and uₒ₂.

The low-pass filtering circuit 2-4-1 extracts the DC bias voltage, Uₛ₁ and Uₛ₂, respectively, from the two voltage signals, uₒ₁1 and uₒ₂.

The 1# bandpass filter amplifier circuit 2-4-2 performs bandpass filtering and amplification on the voltage signals, uₒ₁ and uₒ₂, separately, resulting in the acquisition of the medium-to-low-frequency voltage signals, u_{1L}(f₁), and u_{2L}(f₁), respectively. The 2# bandpass filter amplifier circuit 2-4-3 performs bandpass filtering and amplification on the voltage signals, uₒ₁ and uₒ₂, separately, resulting in the acquisition of the high-frequency voltage signals, u_{1H}(f₂), and u_{2H}(f₂), respectively.

The 1# divider 2-4-4 calculates the quotient A of the medium-to-low-frequency voltage signal u_{1L}(f₁) divided by the DC bias voltage Uₛ₁. The 2# divider 2-4-5 calculates the quotient B of another medium-to-low-frequency voltage signal u_{2L}(f₁) divided by the DC bias voltage Uₛ₂. The 3# divider 2-4-6 calculates the quotient C of the high-frequency voltage signal u_{1H}(f₂) divided by the DC bias voltage Uₛ₁. The 4# divider 2-4-7 calculates the quotient D of another high-frequency voltage signal u_{2H}(f₂) divided by the DC bias voltage Uₛ₂.

The 1# subtractor 2-4-8 calculates the difference between the quotient A and another quotient B to obtain the medium-to-low-frequency voltage signal u_{oL}(f₁). The 2# subtractor 2-4-9 calculates the difference between the quotient c and another quotient D to obtain the high-frequency voltage signal u_{oH}(f₂).

The medium-to-low-frequency voltage signal u_{oL}(f₁) and the high-frequency voltage signal u_{oH}(f₂) are sent to the monitoring and analysis host 2-6 through data acquisition card 2-5.

The monitoring and analysis host 2-6 calculates the wideband voltage signal on the primary side according to the following equation.

u_{oL}(f₁)=G₁kK_{C}u₁(f₁),

u_{oH}(f₂)=G₂kK_{C}u₁(f₂),

Wherein, G₁ and G₂ are the amplification factors of the 1# bandpass filter amplifier circuit 2-4-2 and the 2# bandpass filter amplifier circuit 2-4-3, respectively. u₁(f₁) and u₁(f₂) represent the medium-to-low-frequency voltage component and the high-frequency voltage component, respectively. u₁ is the wideband voltage signal on the primary side loaded at the voltage monitoring terminal, where the voltage monitoring terminal is the high-voltage end of the capacitor voltage divider 1-1. k is the electro-optic coefficient, and K_{C} is the voltage division ratio of the low-voltage capacitor 2-1.

In this embodiment, the 1# photoelectric detector 2-4-11 converts the received optical signal into a voltage signal uₒ₁, while the 2# photoelectric detector 2-4-12 converts the received optical signal into a voltage signal uₒ₂. The expressions for the voltage signals uₒ₁ and uₒ₂ are as follows:

uₒ₁=Uₛ₁(1+kK_{C}u₁),

uₒ₂=Uₛ₂(1−kK_{C}u₁),

Wherein, Uₛ₁ and Uₛ₂ represent the DC bias voltages of uₒ₁ and uₒ₂, respectively.

The expressions for the medium-to-low-frequency voltage signals u_{1L}(f₁) and u_{2L}(f₁) are as follows:

u_{1L}(f₁)=G₁Uₛ₁kK_{C}u₁(f₁),

u_{2L}(f₁)=−G₁Uₛ₂kK_{C}u₁(f₁),

The expressions for the high-frequency voltage signals u_{1H}(f₂) and u_{2H}(f₂) are as follows:

u_{1H}(f₂)=G₂Uₛ₁kK_{C}u₁(f₂),

u_{2H}(f₂)=G₂Uₛ₂kK_{C}u₁(f₂),

Wherein, Uₛ₁ and Uₛ₂ represent the DC bias voltages of uₒ₁ and uₒ₂, respectively.

In this embodiment, the cutoff frequency of the low-pass filter circuit 2-4-1 is set to 0.1 Hz to ensure accurate measurement of low-frequency voltage signals. The lower limit cutoff frequency of the bandpass filter amplifier circuit 1-2-2 is set to 1 Hz, and the upper limit cutoff frequency is set to 10 kHz to ensure accurate measurement of the 50th harmonic voltage signal. The lower limit cutoff frequency of the bandpass filter amplifier circuit 2-4-3 is set to 10 kHz to reduce the influence of low-frequency noise on measurement accuracy, and the upper limit cutoff frequency is set to 50 MHz to ensure accurate measurement of lightning transient voltage signals.

The expression for the terminal voltage u_{C3} of the low-voltage capacitor 2-1 is as follows:

$${u}_{C 3} = \frac{{C}_{1} {C}_{2}}{{C}_{1} {C}_{2} + {C}_{1} {C}_{3} + {C}_{2} {C}_{3}} {u}_{1} = {K}_{C} {u}_{1} ,$$

Wherein, C₁, C₂, and C₃ represent the capacitance values of high-voltage capacitor 1-1-1, medium-voltage capacitor 1-1-2, and low-voltage capacitor 2-1 respectively. K_{C} is the voltage dividing ratio of the low-voltage capacitor 2-1, and u₂ is the wideband voltage signal applied at the primary side of the voltage monitoring terminal.

The proposed optical voltage sensor-based wideband monitoring system for mixed-connected CVT, presented in this embodiment, connects a low-voltage capacitor in series between the low-voltage terminal and the ground terminal of the conventional CVT's medium-voltage capacitor. This forms a voltage divider circuit with the high-voltage capacitor and medium-voltage capacitor of the conventional CVT's capacitor voltage divider. The modification achieved through this approach enables the conventional CVT to have wideband measurement capabilities for both power frequency voltage, harmonic voltage, and transient high-frequency voltage measurements. The low-voltage capacitor used in this invention is made of the same material, structure, and manufacturing process as the high-voltage and medium-voltage capacitors of the conventional CVT's capacitor voltage divider. This not only ensures that the addition of the low-voltage capacitor does not affect the lifespan of the original CVT product but also guarantees that the voltage dividing ratio of the low-voltage capacitor is not affected by temperature variations.

The optical voltage sensor used in this embodiment is a passive sensor composed entirely of optical insulation materials. It does not require a power supply on-site and is connected to the signal processing module located in the control room via an optical cable. It exhibits strong resistance to electromagnetic interference and is less susceptible to adverse electromagnetic environments on-site. It features excellent stability, high reliability, good safety, and strong immunity to electromagnetic interference. In the signal processing unit, a different bandpass filter approach is employed to separate and process the low-frequency voltage signals and high-frequency voltage signals. This effectively improves the signal-to-noise ratio and reduces the impact of noise on measurement accuracy.

While specific embodiments are described in this paper to illustrate the principles and applications of the invention, it should be understood that these embodiments are merely examples and not intended to limit the scope of the invention as defined by the appended claims. It should be understood that numerous modifications can be made to the exemplary embodiments and other arrangements can be devised as long as they do not depart from the spirit and scope of the invention as defined by the appended claims. It should be further understood that different dependent claims and features described in this paper can be combined in ways that are different from those described in the original claims. Additionally, features described in one embodiment can be used in other described embodiments.

What is claimed is:

1. A wideband measurement system for mixed-connected capacitive voltage transformer (CVT) based on an optical voltage sensor, comprising a CVT power frequency measurement section and an optical wideband measurement section;
wherein the optical wideband measurement section comprises a low-voltage capacitor, an optical voltage sensor, a signal processing unit, and a monitoring and analysis host;
the low-voltage capacitor is connected in series between a low-voltage terminal and a ground terminal of a voltage divider in the CVT power frequency measurement section;
electrodes of the optical voltage sensor are connected in parallel to two ends of the low-voltage capacitor;
the optical voltage sensor, triggered by a superluminescent diode (SLD) light source in the signal processing unit, splits a light signal modulated by the low-voltage capacitor into two beams and directs the two beams into the signal processing unit;
the signal processing unit converts the two incoming light signals into two voltage signals being uₒ₁ and uₒ₂, and obtains voltage signals in a medium-to-low frequency range u_{oL}(f₁) and a high-frequency range u_{oH}(f₂); and
the monitoring and analysis host captures the voltage signals in the medium-to-low frequency range u_{oL}(f₁) and the high-frequency range u_{oH}(f₂), and calculates to obtain a wideband voltage signal on a primary side.

2. The wideband measurement system for the mixed-connected CVT based on the optical voltage sensor according to claim 1, wherein the signal processing unit comprises a low-pass filter circuit, a 1# bandpass filter amplifier circuit, a 2# bandpass filter amplifier circuit, a 1# divider, a 2# divider, a 3# divider, a 4# divider, a 1# subtractor, a 2# subtractor, the SLD light source, a 1# photodetector, and a 2# photodetector;
the SLD light source serves as a triggering light source for the optical voltage sensor;
the two beams of light emitted from the optical voltage sensor are respectively converted into the voltage signals uₒ₁ and uₒ₂, by the 1# photodetector and the 2# photodetector;
the low-pass filter circuit extracts the direct-current (DC) bias voltages Uₛ₁ and Uₛ₂ from the two voltage signals uₒ₁ and uₒ₂, respectively;
the 1# bandpass filter amplifier circuit performs bandpass filtering and amplification on the voltage signals uₒ₁ and uₒ₂, resulting in mid-to-low frequency voltage signals u_{1L}(f₁) and u_{2L}(f₁) respectively; similarly, the 2# bandpass filter amplifier circuit applies bandpass filtering and amplification to the voltage signals uₒ₁ and uₒ₂, yielding high-frequency voltage signals u_{1H}(f₂) and u_{2H}(f₂);
the 1# divider calculates a quotient A between the mid-to-low frequency voltage signal u_{1L}(f₁) and the DC bias voltage Uₛ₁; similarly, the 2# divider calculates a quotient B between the mid-to-low frequency voltage signal u_{2L}(f₁) and the DC bias voltage Uₛ₂; the 3# divider calculates a quotient C between the high-frequency voltage signal u_{1H}(f₂) and the DC bias voltage Uₛ₁, while the 4# divider calculates a quotient D between the high-frequency voltage signal u_{2H}(f₂) and the DC bias voltage Uₛ₂;
the 1# subtractor takes a difference between the quotient A and the quotient B to obtain the mid-to-low frequency voltage signal u_{oL}(f₁); similarly, the 2# subtractor calculates a difference between the quotient C and the quotient D to obtain the high-frequency voltage signal u_{oH}(f₂).

3. The wideband measurement system for the mixed-connected CVT based on the optical voltage sensor according to claim 2, wherein the monitoring and analysis host calculates the wideband voltage signal on the primary side according to the following equation:
u_{oL}(f₁)=G₁kK_{C}u₁(f₁),
u_{oH}(f₂)=G₂kK_{C}u₁(f₂),
wherein G₁ and G₂ are amplification factors of the 1# bandpass filter amplifier circuit and the 2# bandpass filter amplifier circuit, respectively; u₁(f₁) and u₁(f₂) represent a low-frequency voltage component and a high-frequency voltage component, respectively; u₁ denotes the wideband voltage signal loaded on the primary side of a voltage monitoring terminal, wherein the voltage monitoring terminal is a high-voltage end of the voltage divider; k is a electro-optic constant, and K_{C} is a voltage division ratio of the low-voltage capacitor.

4. The wideband measurement system for the mixed-connected CVT based on the optical voltage sensor according to claim 3, wherein the 1# photodetector converts a received optical signal into a voltage signal uₒ₁; similarly, the 2# photodetector converts a received optical signal into a voltage signal uₒ₂; expressions for the voltage signals uₒ₁ and uₒ₂ are as follows:
uₒ₁=Uₛ₁(1+kK_{C}u₁),
uₒ₂=Uₛ₂(1−kK_{C}u₁),
wherein Uₛ₁ and Uₛ₂ are the DC bias voltages for uₒ₁ and uₒ₂, respectively.

5. The wideband measurement system for the mixed-connected CVT based on the optical voltage sensor according to claim 3, wherein expressions of the mid-to-low frequency voltage signals u_{1L}(f₁) and u_{2L}(f₁) are as follows:
u_{1L}(f₁)=G₁Uₛ₁kK_{C}u₁(f₁),
u_{2L}(f₁)=−G₁Uₛ₂kK_{C}u₁(f₁),
expressions for the high-frequency voltage signals u_{1H}(f₂) and u_{2H}(f₂) are as follows:
u_{1H}(f₂)=G₂Uₛ₁kK_{C}u₁(f₂),
u_{2H}(f₂)=−G₂Uₛ₂kK_{C}u₁(f₂),
wherein Uₛ₁ and Uₛ₂ are the DC bias voltages for uₒ₁ and uₒ₂, respectively.

6. The wideband measurement system for the mixed-connected CVT based on the optical voltage sensor according to claim 5, wherein a cutoff frequency of 0.1 Hz is configured for the low-pass filter circuit;
a lower limit cutoff frequency of the 1# bandpass filter amplifier circuit is set to 1 Hz, while an upper limit cutoff frequency is chosen as 10 kHz;
a lower limit cutoff frequency of the 2# bandpass filter amplifier circuit is set to 10 kHz, while an upper limit cutoff frequency is chosen as 50 MHz.

7. The wideband measurement system for the mixed-connected CVT based on the optical voltage sensor according to claim 1, wherein the mid-to-low frequency voltage signal u_{oL}(f₁) and the high-frequency voltage signal u_{oH}(f₂) are transmitted to the monitoring and analysis host via a data acquisition card.

8. The wideband measurement system for the mixed-connected CVT based on the optical voltage sensor according to claim 1, wherein a voltage limiting device is configured in the optical wideband measurement section; the voltage limiting device is connected in parallel across the low-voltage capacitor.

9. The wideband measurement system for the mixed-connected CVT based on the optical voltage sensor according to claim 1, wherein the voltage divider comprises a series connection of a high-voltage capacitor and a mid-voltage capacitor; the low-voltage capacitor is connected in series between the low-voltage terminal of the mid-voltage capacitor and the ground terminal;
an expression for a terminal voltage u_{C3} of the low-voltage capacitor is as follows:
$${u}_{C 3} = \frac{{C}_{1} {C}_{2}}{{C}_{1} {C}_{2} + {C}_{1} {C}_{3} + {C}_{2} {C}_{3}} {u}_{1} = {K}_{C} {u}_{1} ,$$
wherein C₁, C₂, and C₃ represent capacitance values of the high-voltage capacitor, the mid-voltage capacitor, and the low-voltage capacitor respectively; K_{C} is a voltage division ratio of the low-voltage capacitor, and u₁ is the wideband voltage signal loaded on a voltage monitoring terminal of the primary side.

10. The wideband measurement system for the mixed-connected CVT based on the optical voltage sensor according to claim 9, wherein the low-voltage capacitor comprises the same material as the high-voltage capacitor and the mid-voltage capacitor.
